(19) United States
(12) Patent Application Publication
(10) Pub. No.: US 2017/0256626 A1
(43) Pub. Date: Sep. 7, 2017

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Keiichi MATSUSHITA, Tokyo (JP)

(73) Assignee: Kabushiki Kaisha Toshiba, Minato-ku (JP)

(21) Appl. No.: 15/299,572

(22) Filed: Oct. 21, 2016

(30) Foreign Application Priority Data
Mar. 2, 2016 (JP) 2016-039964

(51) Int. Cl. H01L 29/51; H01L 21/324; H01L 21/02; H01L 29/20; H01L 29/36

(52) U.S. Cl. CPC H01L 29/518; H01L 29/2003; H01L 29/36; H01L 21/0217; H01L 21/02274; H01L 21/324

(57) ABSTRACT

A semiconductor device includes a substrate, a nitride semiconductor layer formed on the substrate, a gate electrode formed on the nitride semiconductor layer; and a silicon nitride layer which coats the gate electrode and is formed on the nitride semiconductor layer, wherein the silicon nitride layer has a refractive index of less than 1.9 at the nitride semiconductor layer side.

### CROSS-REFERENCE TO RELATED APPLICATION

This application is based upon and claims the benefit of priority from the prior Japanese Patent Application No. 2016-039964, filed on Mar. 2, 2016, the entire contents of which are incorporated herein by reference.

### FIELD

Embodiments of the present invention relate to a semiconductor device and a manufacturing method of a semiconductor device.

### BACKGROUND

There are semiconductor devices to use a nitride semiconductor using gallium nitride (GaN), for semiconductor devices for high power to be used in a communication apparatus or the like. As semiconductor devices for high power, semiconductor devices of a HEMT structure in which a layer (an AlGaN layer) of aluminum gallium nitride containing aluminum element (Al) is formed on a layer (a GaN layer) of gallium nitride are known.

Conventionally, a silicon nitride (SiN) layer is further formed, as a surface protective layer (a passivation layer), on the AlGaN layer, to suppress the adhesion of impurities onto the AlGaN layer, thereby stabilizing the surface state of the semiconductor device. It is known that a silicon nitride layer which is laminated on the AlGaN layer and whose refractive index is not less than 2.0 has an effect of the stress reduction and collapse reduction of the silicon nitride layer.

However, when a refractive index of a silicon nitride layer becomes high, an electric conductivity thereof becomes high. For this reason, when a silicon nitride layer with a high refractive index is used as a surface protective layer, electrons flows from a gate electrode into the silicon nitride layer, and the electrons form a trap level, and as its result, problems such as to cause the deterioration of characteristics of the semiconductor device, and the drop of a life of the semiconductor device are generated.

### BRIEF DESCRIPTION OF THE DRAWINGS

FIG. 1 is a sectional diagram of a semiconductor device of a first embodiment.

FIG. 2 is a sectional diagram of the vicinity of a gate electrode of the first embodiment.

FIG. 3A is a transition diagram of a current decreasing rate over time of the semiconductor device of the first embodiment.

FIG. 3B is a transition diagram of a current decreasing rate over time of a semiconductor device of a comparative example.

FIG. 4 is a sectional diagram of a semiconductor device of a modification of the first embodiment.

FIG. 5A and FIG. 5B are diagrams illustrating a process of laminating the nitride semiconductor layer on the substrate.

FIG. 6A is a diagram showing a process of laminating the silicon nitride layer.

FIG. 6B is a diagram illustrating a process of forming hole portions for electrode in the silicon nitride layer.

FIG. 7A is a diagram illustrating a process of arranging respective electrodes of the semiconductor device of the first embodiment.

FIG. 7B is a diagram illustrating a process of laminating the silicon nitride layer of the semiconductor device of the first embodiment.

FIG. 8A is a diagram illustrating a process of arranging respective electrodes of a semiconductor device of a modification of the first embodiment.

FIG. 8B is a diagram illustrating a process of laminating a silicon nitride layer of the semiconductor device of the modification of the first embodiment.

FIG. 9 is a sectional diagram of a semiconductor device of a second embodiment.

FIG. 10A is a diagram illustrating a process of arranging respective electrodes of the semiconductor device of the second embodiment.

FIG. 10B is a diagram illustrating a process of laminating a silicon nitride layer of the semiconductor device of the second embodiment.

### DETAILED DESCRIPTION

A semiconductor device of an embodiment includes a substrate, a nitride semiconductor layer formed on the substrate, a gate electrode formed on the nitride semiconductor layer, and a silicon nitride layer which coats the gate electrode and is formed on the nitride semiconductor layer, wherein the silicon nitride layer has a refractive index of less than 1.9 at the nitride semiconductor layer side.

A manufacturing method of a semiconductor device of an embodiment includes: making silane gas and ammonia gas into plasma, to form a first silicon nitride layer having a refractive index of less than 1.9 on a semiconductor layer of a semiconductor substrate; forming a hole portion in the first silicon nitride layer by etching; forming a gate electrode on the semiconductor layer in the hole portion, and joining the gate electrode to the semiconductor layer; and making silane gas and ammonia gas into plasma, to form a second silicon nitride layer on the gate electrode.

Embodiments provide a semiconductor device having a silicon nitride layer as a surface protective layer that reduces electrons flowing therein from a gate electrode, and that suppresses formation of the trap level in an interface of it and a nitride semiconductor layer.

Hereinafter, embodiments to practice the invention will be described based on the drawings.

### First Embodiment

### Structure

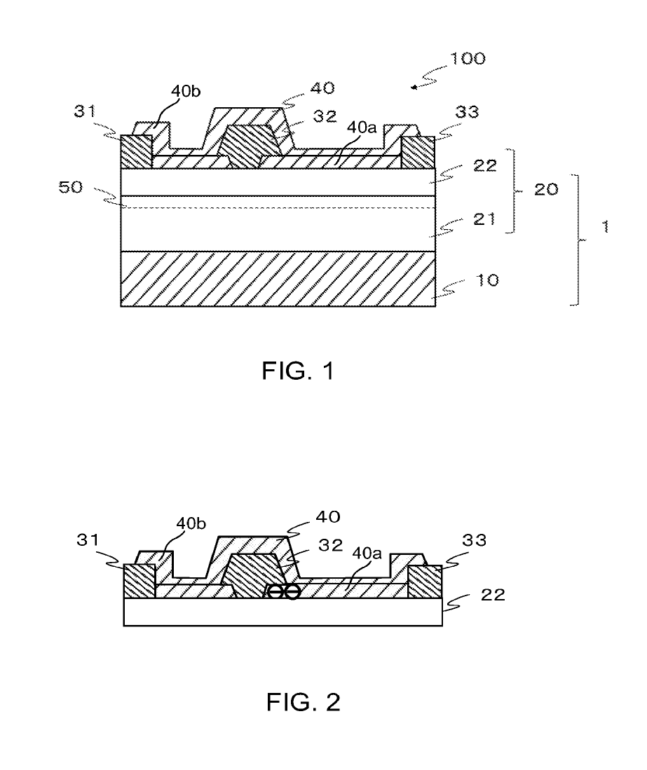

FIG. 1 is a sectional diagram of a semiconductor device 100 according to a first embodiment. The semiconductor device 100 is a field effect transistor (FET).

A gallium nitride layer 21 as a channel layer is formed on a substrate 10. An aluminum gallium nitride layer 22 as a barrier layer is formed on the gallium nitride layer 21. In the present embodiment, the gallium nitride layer 21 and the aluminum gallium nitride layer 22 are collectively made to be a nitride semiconductor layer 20. A semiconductor substrate 1 has the substrate 10 and the nitride semiconductor layer 20.

A source electrode 31, a gate electrode 32 and a drain electrode 33 are provided on the aluminum gallium nitride layer 22. The source electrode 31, the gate electrode 32 and the drain electrode 33 are provided separately to each other. The source electrode 31 and the drain electrode 33 are provided so as to sandwich the gate electrode 32 therebetween.

A silicon nitride layer 40 as a surface protective layer is provided on the aluminum gallium nitride layer 22, the source electrode 31, the gate electrode 32 and the drain electrode 33. The silicon nitride layer 40 coats the gate electrode 32. The silicon nitride layer 40 has a first silicon nitride layer 40a and a second silicon nitride layer 40b.

As a material of the substrate 10, there are silicon (Si), silicon carbide (SiC), sapphire, gallium nitride (GaN), and diamond and so on. However, in the present embodiment, the material of the substrate 10 is not limited to these.

Each of the gallium nitride layer 21 and the aluminum gallium nitride layer 22 is a nitride semiconductor. In the present embodiment, each of these layers is a III-V group semiconductor in which a III group element of aluminum (Al), gallium (Ga), and a V group element of nitrogen (N) are combined.

Respective band gaps of the gallium nitride layer 21 and the aluminum gallium nitride layer 22 are different to each other. When the gallium nitride layer 21 and the aluminum gallium nitride layer 22 are joined, a quantum well of an energy level is formed in the vicinity of the junction face (hetero interface) thereof, and electrons are accumulated in the quantum well in the high density, to form two dimensional electron gas (2 Dimensional Electron Gas: 2DEG) 50.

Each of the source electrode 31 and the drain electrode 33 is in contact with the aluminum gallium nitride layer 22 by ohmic contact. The gate electrode 32 is in contact with the aluminum gallium nitride layer 22 by schottky contact.

The first silicon nitride layer 40a coats an upper surface of the aluminum gallium nitride layer 22, to terminate the dangling bond on the surface of the aluminum gallium nitride layer 22. That is, the first silicon nitride layer 40a prevents that a trap level is formed on the surface of the aluminum gallium nitride layer 22, thereby suppress the deterioration of characteristics of the semiconductor device 100. In addition, the second silicon nitride layer 40b coats the gate electrode 32 and so on, thereby having a role to protect each electrode from moisture or the like.

The refractive index of the first silicon nitride layer 40a is less than 1.9. That is, the silicon nitride layer 40 has a refractive index of less than 1.9 at its nitride semiconductor 20 side. When the refractive index is high, the electric conductivity of the silicon nitride layer 40 is high. The refractive index of Si₃N₄ is about 2.0, and it is known that the value of the refractive index is smaller as the silicon content rate is smaller. For this reason, the Si contained amount of the first silicon nitride layer 40a of the present embodiment is smaller than that of usual silicon nitride. The refractive index of the silicon nitride layer in the present invention has been measured using a light with a wavelength in the range of 500 nm-2500 nm.

FIG. 2 is a sectional diagram of the vicinity of the gate electrode of the present embodiment. When a voltage is applied to the gate electrode 32, electrons in the gate electrode 32 sometimes flow from the electrode end into the silicon nitride layer 40. The electrons which have flowed into the silicon nitride layer 40 charge the drain electrode 33 side among the gate electrode ends, to form a trap level.

Regarding the distribution of electric field strength in the semiconductor device, the electric field strength becomes the largest under the gate electrode. For this reason, the place under the gate electrode becomes a heat generating source.

Since the trap level formed at the gate electrode end attracts electrons in the two dimensional electron gas passing under the gate electrode, it causes the deterioration of a saturation electron speed, and an electron mobility. In addition, the heat generation caused by electric field strength decreases current remarkably.

In the semiconductor device of the present embodiment, since the refractive index of the first silicon nitride layer 40a is less than 1.9, the electric conductivity of the first silicon nitride layer 40a becomes lower, and the electrons flowing from the gate electrode 32 into the first silicon nitride layer 40a becomes smaller. By this means, the formation of a trap level is suppressed, and the deterioration of a saturation electron speed and an electron mobility, and the current decrease caused by the heat generation can be suppressed.

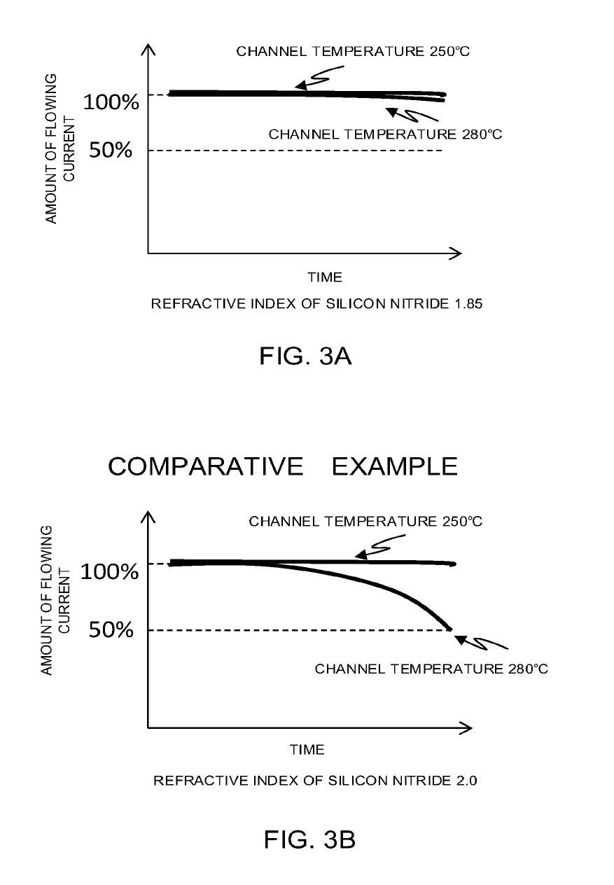

FIG. 3A is a transition diagram of a current decreasing rate over time of the semiconductor device of the first embodiment. FIG. 3B is a transition diagram of a current decreasing rate over time of a semiconductor device of a comparative example. FIG. 3A is a transition diagram of current decreasing rates in cases in which the refractive index of the first silicon nitride layer 40a is 1.85, and the channel temperatures are 250° C. and 280° C. In addition, FIG. 3B is a transition diagram of current decreasing rates in cases in which the refractive index of the first silicon nitride layer 40a is 2.0, and the channel temperatures are 250° C. and 280° C.

In any of the semiconductor device in which the refractive index of the first silicon nitride layer 40a is 1.85, and the semiconductor device in which the refractive index of the first silicon nitride layer 40a is 2.0, an amount of a flowing current is approximately constant irrespective of lapse of time, when the channel temperature is 250° C. (FIG. 3A, FIG. 3B).

In the semiconductor device in which the refractive index of the first silicon nitride layer 40a is 2.0, when the channel temperature is 280° C., decreasing of the current amount increases with lapse of time, and the current amount decreases to about 50% of an initial current amount (FIG. 3B).

In contrast, the semiconductor device in which the refractive index of the first silicon nitride layer 40a is 1.85, when the channel temperature is 280° C., decreasing of the current amount is small, and it is possible to maintain the current amount approximately equal to that at the channel temperature 250° C. (FIG. 3A).

In the case of the semiconductor device using a nitride semiconductor, when a high voltage is applied to it, the channel temperature thereof sometimes increases to about 280° C. For this reason, in the semiconductor device according to the present embodiment in which the refractive index of the first silicon nitride layer 40a is less than 1.9, even when the channel temperature increases, the current amount can be maintained, and the current decrease caused by the heat generation can be suppressed.

### Structure of Modification

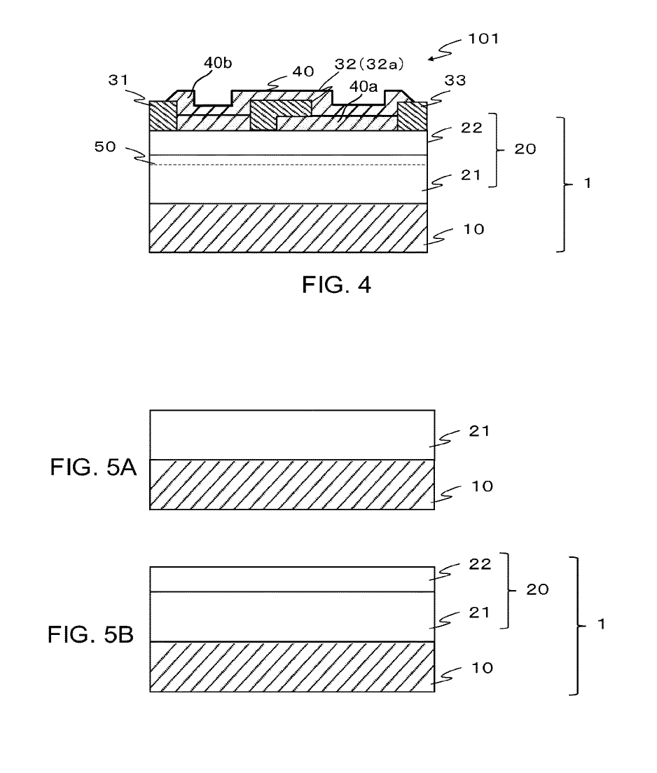

FIG. 4 is a sectional diagram of a semiconductor device of a modification of the first embodiment. In a semiconductor device 101 of the modification, the gate electrode 32 has a field plate structure 32a.

When the gate electrode has a field plate structure, the concentration of electric field strength under the gate electrode can be suppressed, and the heat generation can be suppressed. But when the gate electrode has a field plate structure, the contact area of the gate electrode 32 (32a) and the first silicon nitride layer 40a increases, and an area in which a trap level is formed increases.

In the semiconductor device of the present modification, the refractive index of the first silicon nitride layer 40a is made less than 1.9, and thus the semiconductor device suppresses electrons from flowing from the gate electrode 32 (32a) into the first silicon nitride layer 40a. By this means, the formation of a trap level is suppressed, and the deterioration of a saturation electron speed and an electron mobility, and the current decrease caused by the heat generation can be suppressed.

### Manufacturing Method

A manufacturing method of the semiconductor device 100 of the present embodiment will be described below.

FIG. 5A to FIG. 7B are diagrams illustrating a manufacturing process of the semiconductor device 100 of the present embodiment.

FIG. 5A, FIG. 5B are diagrams illustrating a manufacturing method of the semiconductor substrate 1, and are diagrams illustrating a process of laminating the nitride semiconductor layer 20 on the substrate 10.

GaN is epitaxially grown on the substrate 10 by an MOCVD (Metal Organic Chemical Vapor Deposition) method or the like, and the gallium nitride layer 21 is laminated on the substrate 10 (FIG. 5A). The MOCVD method is a method in which organic metal and carrier gas are supplied on the substrate 10, and a vapor chemical reaction of them is caused on the heated substrate 10, to epitaxially grow a semiconductor layer on the substrate 10.

After the gallium nitride layer 21 has been laminated on the substrate 10, trimethylaluminum (TMA), trimethylgallium (TMG) of organic metal material, and ammonia gas are supplied along with carrier gas (nitrogen and hydrogen), and they are reacted, and the aluminum gallium nitride layer 22 is laminated on the gallium nitride layer 21 (FIG. 5B).

However, a laminating method of the aluminum gallium nitride layer 22 by an MOCVD method is an example, and in the present embodiment, a laminating method of the aluminum gallium nitride layer 22 is not limited to an MOCVD method.

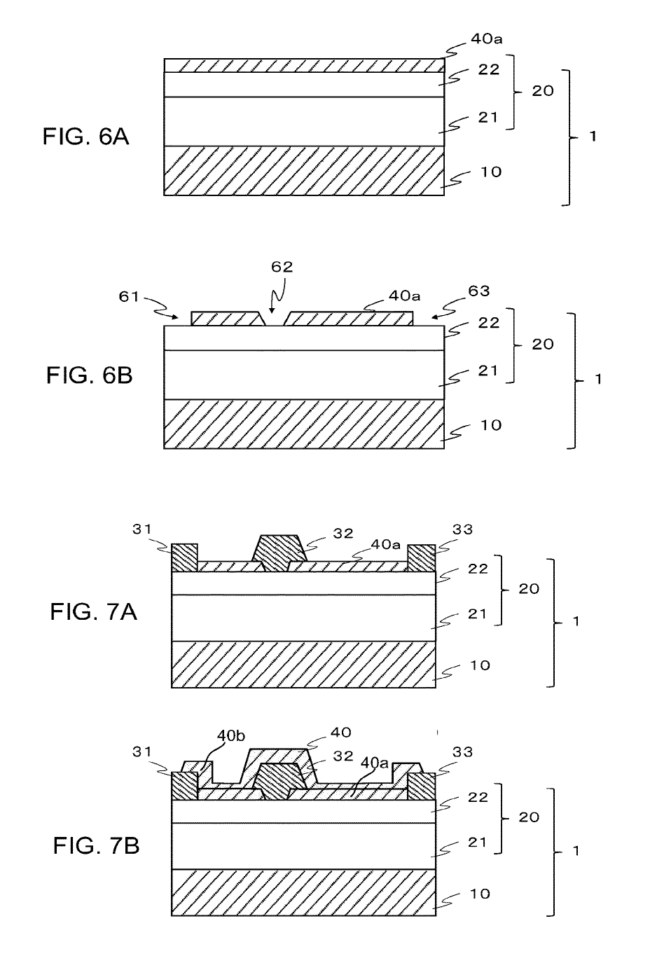

FIG. 6A is a diagram illustrating a process of laminating the first silicon nitride layer 40a with a refractive index of less than 1.9 on the aluminum gallium nitride layer 22 after the aluminum gallium nitride layer 22 has been laminated. FIG. 6B is a diagram illustrating a process of forming hole portions 61, 62, 63 for arranging the respective electrodes 31, 32, 33 in the first silicon nitride layer 40a.

In the present embodiment, the silicon nitride layer 40 is laminated separately two times by a plasma CVD (Plasma-enhanced Chemical Vapor Deposition) method. A first lamination is performed before the respective electrodes 31, 32, 33 are provided, and a second lamination is performed after the respective electrodes 31, 32, 33 have been provided.

In the present embodiment, the substrate 10 on which the gallium nitride layer 21 and the aluminum gallium nitride layer 22 have been laminated is placed in a chamber of a plasma CVD apparatus. Then, silane gas (SiH₄) and ammonia gas (NH₃) of raw material gas are injected in the chamber, and RF wave and so on are applied, to make the raw material gas into a plasma state. Si ions and N ions are deposited on the aluminum gallium nitride layer 22, to form the first silicon nitride layer 40a.

At this time, amounts of silane gas (SiH₄) and ammonia gas (NH₃) of the raw material gas to be injected are adjusted, so that the refractive index of the first silicon nitride layer 40a becomes less than 1.9. Generally, a silicon nitride layer formed by deposition by a plasma CVD method tends to contain a large Si component. A refractive index of a silicon nitride layer having a large Si component becomes high.

After the first silicon nitride layer 40a with a refractive index of less than 1.9 has been formed, the hole portions 61, 62, 63 are formed by ion etching at respective positions where the source electrode 31, the gate electrode 32, the drain electrode 33 are to be formed. That is, a resist material is applied to the portion except the respective places where the hole portions 61, 62, 63 of the first silicon nitride layer 40a are to be formed, and then the first silicon nitride layer 40a is irradiated with ion beam. At the places to which the resist material has not been applied, that is the respective places where the hole portions 61, 62. 63 are to be formed, the first silicon nitride layer 40a is subjected to etching. By this means, the hole portions 61, 62, 63 are formed. Then, the resist material is removed (FIG. 6B).

FIG. 7A is a diagram illustrating a process of arranging the respective electrodes 31, 32, 33 after the hole portions 61, 62, 63 have been formed in the first silicon nitride layer 40a with a refractive index of less than 1.9. FIG. 7B is a diagram illustrating a process of laminating the second silicon nitride layer 40b on the first silicon nitride layer 40a and on the respective electrodes 31, 32, 33.

Titanium (Ti) and aluminum (Al) are deposited in this order in the hole portion 61 and the hole portion 63, to respectively form the source electrode 31 and the drain electrode 33 on the aluminum gallium nitride layer 22, and the source electrode 31 and the drain electrode 33 are made ohmic contact with the aluminum gallium nitride layer 22 by heat treatment. Then, nickel (Ni) and gold (Au) are deposited in this order in the hole portion 62, to form the gate electrode 32 on the aluminum gallium nitride layer 22, and the gate electrode 32 is made schottky contact with the aluminum gallium nitride layer 22 by heat treatment.

After the respective electrodes 31, 32, 33 have been formed on the aluminum gallium nitride layer 22, the second silicon nitride layer 40b is formed on the first silicon nitride layer 40a, and on the respective electrodes 31, 32, 33, by a plasma CVD method. The silicon nitride layer 40 is formed by the first silicon nitride layer 40a and the second silicon nitride layer 40b.

In addition, after the first silicon nitride layer 40a with a refractive index of less than 1.9 has been formed, and before the hole portions 61, 62, 63 are formed, a heat treatment may be performed at 600° C.-900° C. in order to desorb hydrogen element (H) contained in the first silicon nitride layer 40a.

When silane gas (SiH₄) and ammonia gas (NH₃) are used as the raw material gas of the first silicon nitride layer 40a, the first silicon nitride layer 40a containing hydrogen element (H) is formed. When a large amount of hydrogen atoms are contained therein, the hydrogen atom (H) combines with an unterminated atom at the interface of the aluminum gallium nitride layer 22 and the first silicon nitride layer 40a, to form a level, and by this means, the characteristics of the semiconductor device sometimes deteriorates. For this reason, a heat treatment is performed, in order to desorb the hydrogen element (H) contained in the first silicon nitride layer 40a. That is, the contained amount of the impurity atoms in the first silicon nitride layer 40a is smaller than that in the silicon nitride not subjected to heat treatment.

When the first silicon nitride layer 40a is subjected to heat treatment at not less than 600° C., desorption of the hydrogen element (H) is effectively performed. However, when the heat treatment is performed at not less than 1000° C., the composition of the gallium nitride layer 21 and the aluminum gallium nitride layer 22 may possibly be affected. For this reason, the range of 600° C. to 900° C. is effective, as the temperature of the heat treatment.

### Manufacturing Method of Modification

A manufacturing method of the semiconductor device 101 of the modification of the first embodiment will be described.

A process of laminating the nitride semiconductor layer 20 on the substrate 10, and a process of laminating the first silicon nitride layer 40a and of forming the hole portions 61, 62, 63 for electrode are respectively the same as the processes illustrated in FIG. 5A, FIG. 5B, FIG. 6A and FIG. 6B.

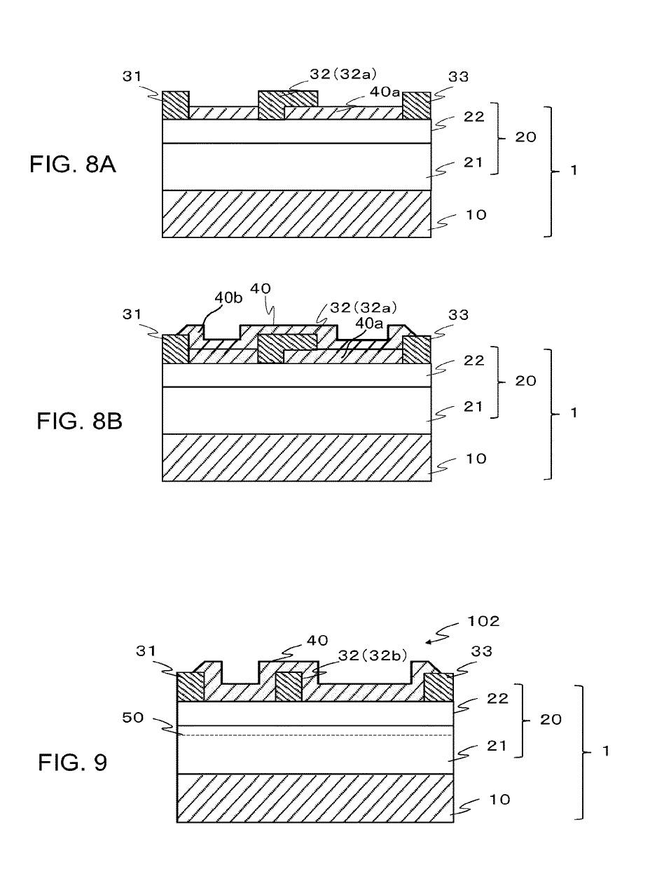

FIG. 8A is a diagram illustrating a process of arranging the respective electrodes 31, 32, 33 after the hole portions 61, 62, 63 have been formed in the first silicon nitride layer 40a with a refractive index of less than 1.9. FIG. 8B is a diagram illustrating a process of laminating the second silicon nitride layer 40b on the first silicon nitride layer 40a and on the respective electrodes 31, 32, 33.

A forming method of the source electrode 31 and the drain electrode 33 is the same as that of the first embodiment. The gate electrode 32 has the field plate structure 32a, and nickel (Ni) and gold (Au) are deposited in the hole portion 62 and on the silicon nitride layer 40a, to form the gate electrode 32 (32a) of the field plate structure. Then the gate electrode 32 is made contact with on the aluminum gallium nitride layer 22 by schottky contact.

After the respective electrodes 31, 32, 33 have been formed on the aluminum gallium nitride layer 22, the second silicon nitride layer 40b is formed on the first silicon nitride layer 40a, and on the respective electrodes 31, 32, 33, by a plasma CVD method. The silicon nitride layer 40 is formed by the first silicon nitride layer 40a and the second silicon nitride layer 40b.

With the above-described structure, each of the semiconductor devices 100, 101 of the first embodiment and the modification of the first embodiment suppresses electrons from flowing from the gate electrode 32 (32a) into the first silicon nitride layer 40a because the refractive index of the first silicon nitride layer 40a is less than 1.9. By this means, at the interface between the first silicon nitride layer 40a and the aluminum gallium nitride layer 22, a trap level caused by accumulation of electrons is suppressed, and each of the semiconductor devices of the first embodiment and the modification of the first embodiment has an effect to suppress the deterioration of characteristics of the semiconductor device, and the deterioration of a life of the semiconductor device.

In addition, in the present embodiment, since formation of a trap level is generated in the vicinity of the gate electrode 32, the first silicon nitride layer 40a and the second silicon nitride layer 40b may be formed so as to coat only the gate electrode 32.

### Second Embodiment

### Structure

FIG. 9 is a sectional diagram of a semiconductor device 102 of a second embodiment. In the second embodiment, a sectional shape of a gate electrode 32b is rectangular.

Since the gate electrode 32b of the present embodiment is not formed on the silicon nitride layer 40 with a refractive index of less than 1.9, regarding the electric field strength distribution under the gate electrode 32b, a peak value thereof becomes larger than that in the first embodiment. For this reason, the semiconductor device 102 of the present embodiment becomes easy to generate heat compared with the semiconductor device 100 of the first embodiment. However, the formation of the silicon nitride layer 40 by a plasma CVD method can be performed by one time, not separately by two times as in the first embodiment. In the present embodiment, since the refractive index of the silicon nitride layer 40 is less than 1.9, the refractive index of the silicon nitride layer 40 at the nitride semiconductor side is less than 1.9.

### Manufacturing Method

A manufacturing method of the semiconductor device 102 of the present embodiment will be described below.

Regarding a manufacturing method of the second embodiment, a manufacturing method of the semiconductor substrate 1, that is, a process of laminating the nitride semiconductor layer 20 on the substrate 10, is the same as the process illustrated in FIG. 5A, FIG. 5B.

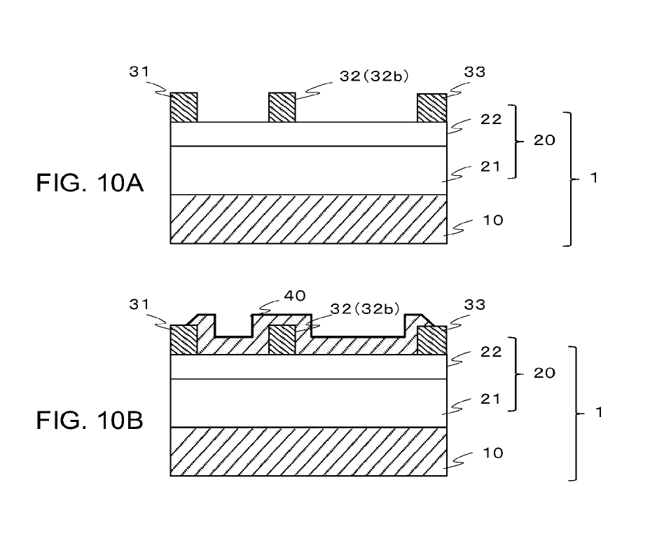

FIG. 10A is a diagram illustrating a process of arranging the respective electrodes 31, 32, 33 of the semiconductor device of the present embodiment. FIG. 10B is a diagram illustrating a process of laminating the silicon nitride of the semiconductor device of the present embodiment.

Titanium (Ti) and aluminum (Al) are deposited in this order on the aluminum gallium nitride layer 22 of the semiconductor substrate 1, to form the source electrode 31 and the drain electrode 33, and the source electrode 31 and the drain electrode 33 are made contact with the aluminum gallium nitride layer 22 by ohmic contact by heat treatment (FIG. 10A). Then, nickel (Ni) and gold (Au) are deposited in this order on the aluminum gallium nitride layer 22, to form the gate electrode 32 (32b), and the gate electrode 32 (32b) is made contact with the aluminum gallium nitride layer 22 by schottky contact by heat treatment (FIG. 10A).

Then, amounts of the silane gas (SiH₄) and the ammonia gas (NH₃) of the raw material gas to be injected are adjusted so that the refractive index of the silicon nitride layer 40 becomes less than 1.9, and the silicon nitride layer 40 with a refractive index of less than 1.9 is formed on the respective electrodes 31, 32, 33 and on the aluminum gallium nitride layer 22, by a plasma CVD method (FIG. 10B).

Note that, in the present embodiment, since formation of a trap level is generated in the vicinity of the gate electrode 32b, the silicon nitride layer 40 with a refractive index of less than 1.9 may be formed so as to coat only the gate electrode 32b.

With the above-described structure, each of the semiconductor devices 100, 101 of the first embodiment and the modification of the first embodiment suppresses electrons from flowing from the gate electrode 32 (32b) into the first silicon nitride layer 40a because the refractive index of the first silicon nitride layer 40a is less than 1.9. By this means, at the interface between the first silicon nitride layer 40a and the aluminum gallium nitride layer 22, a trap level caused by accumulation of electrons is suppressed, and each of the semiconductor devices 100, 101 has an effect to suppress the deterioration of characteristics of the semiconductor device, and the deterioration of a life thereof.

The semiconductor device 102 of the second embodiment suppresses electrons from flowing from the gate electrode 32b into the silicon nitride layer 40 because the refractive index of the silicon nitride layer 40 is less than 1.9. By this means, at the interface between the silicon nitride layer 40 and the aluminum gallium nitride layer 22, a trap level caused by accumulation of electrons is suppressed, and the semiconductor device 102 has an effect to suppress the deterioration of characteristics of the semiconductor device, and the deterioration of a life thereof.

In the above-described embodiments and modification, the nitride semiconductor layer 20 has a HEMT structure having two kinds of the nitride semiconductor layers, but the present invention in not limited to this. The semiconductor device may have a MOSFET structure, and the nitride semiconductor layer 20 may have three or more kinds of nitride semiconductor layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a nitride semiconductor layer formed on the substrate;
a gate electrode formed on the nitride semiconductor layer; and
a silicon nitride layer which coats the gate electrode and is formed on the nitride semiconductor layer, wherein the silicon nitride layer has a refractive index of less than 1.9 at the nitride semiconductor layer side.

2. The semiconductor device according to claim 1, wherein a contained amount of impurity atoms in the silicon nitride layer is smaller than a contain amount of impurity atoms of silicon nitride which has not been subjected to heat treatment.

3. The semiconductor device according to claim 1, wherein the nitride semiconductor layer has layers of at least two kinds of nitride semiconductors.

4. The semiconductor device according to claim 1, wherein:
the silicon nitride layer includes a first silicon nitride layer having a refractive index of less than 1.9, and a second silicon nitride layer;
the first silicon nitride layer has a hole portion, and is formed on the nitride semiconductor layer;
the gate electrode is formed on the nitride semiconductor layer in the hole portion; and
the second silicon nitride layer coats the gate electrode, and is formed on the first silicon nitride layer.

5. The semiconductor device according to claim 1, wherein:
a refractive index of the silicon nitride layer is less than 1.9.

6. A manufacturing method of a semiconductor device, comprising:
forming a gate electrode on a semiconductor layer of a semiconductor substrate, and joining the gate electrode to the semiconductor layer; and
making silane gas and ammonia gas into plasma, to form a silicon nitride layer having a refractive index of less than 1.9 on the semiconductor layer.

7. A manufacturing method of a semiconductor device, comprising:
making silane gas and ammonia gas into plasma, to form a first silicon nitride layer having a refractive index of less than 1.9 on a semiconductor layer of a semiconductor substrate;
forming a hole portion in the first silicon nitride layer by etching;
forming a gate electrode on the semiconductor layer in the hole portion, and joining the gate electrode to the semiconductor layer; and
making silane gas and ammonia gas into plasma, to form a second silicon nitride layer on the gate electrode.

8. The manufacturing method of a semiconductor device according to claim 7, further comprising:
performing a heat treatment of the first silicon nitride layer at a temperature range of 600° C. to 900° C. after forming the first silicon nitride layer.
